(19) United States
(12) Patent Application Publication
(10) Pub. No.: US 2006/0197140 A1
(43) Pub. Date: Sep. 7, 2006

(54) Vertical transistor NVM with body contact structure and method

(75) Inventors: Ramachandran Muralidhar, Austin, TX (US); Yang Du, Austin, TX (US); Leo Mathew, Austin, TX (US)

Correspondence Address: FORTKORT GRETHER & KELTON LLP, 8911 N. CAPITAL OF TEXAS HWY., SUITE 3200, AUSTIN, TX, 78759, US

(73) Assignee: Freescale Semiconductor, Inc.

(21) Appl. No.: 11/072,878

(22) Filed: Mar. 4, 2005

(51) Int. Cl. H01L 29/788

(52) U.S. Cl. 257/315

(57) ABSTRACT

A semiconductor device (151) is provided which comprises (a) a semiconductor substrate (103); (b) a fin (109) comprising a semiconductor material and being in electrical contact with the substrate; (c) a first floating gate (121) disposed on a first side of said fin; and (d) a control gate (107).

### RELATED APPLICATIONS

This application is related to commonly assigned U.S. patent application Ser. No. 10/074,732, entitled “Method Of Forming A Vertical Double Gate Semiconductor Device”, filed on Feb. 13, 2002 by Mathew et al.

### FIELD OF THE DISCLOSURE

The present disclosure relates generally to the field of semiconductor fabrication, and more particularly, to a process for forming FinFET non-volatile memory devices with body contact.

### BACKGROUND OF THE DISCLOSURE

Some memory devices, such as flash memory devices or other types of Non-Volatile RAM (NVRAM) devices, utilize a transistor with a floating gate structure for storing a charge that is indicative of a value being stored in a memory cell implemented by the transistor. The ratio of the capacitance between a control gate and a floating gate of a transistor to the capacitance between the floating gate and a channel region of the transistor affects the ability to read and write to a memory cell implemented by the transistor. Typically, it is desirable to have a larger capacitance between the control gate and the floating gate than between the floating gate and the channel region.

As with other semiconductor devices, there has been a continuing movement in the art toward non-volatile RAM devices of increased density. One method for increasing the density of CMOS devices is to build structures vertically from the surface of the semiconductor wafer. This has led to the development of non-volatile RAM devices having a FinFET CMOS architecture. Such devices have a series of fins which extend vertically from the substrate and which are used to build the FET structures.

One example of a FinFET device is depicted in FIG. 1. The device depicted therein is fabricated on a dielectric layer 2 and includes a silicon drain island 4 and a source island 6 that are connected by a silicon fin 8. The source, drain, and channel are covered by a dielectric layer or hard mask 9 during a stage of the process, and a gate 11 extends across both sides of the fin 8 and is isolated from the fin by a gate oxide (not shown). Thus, inversion layers are formed on both sides of the fin.

FinFET CMOS structures of the type depicted in FIG. 1 have several advantages over other FET structures. In particular, this type of structure has the advantage of providing double gates to effectively suppress the short channel effect and to enhance drive current. Also, since the surfaces of the fins are parallel planes, parasitic corner effects are overcome. Moreover, since the fin is very thin, doping of the fin is not required in order to suppress the short channel effect.

However, while FINFET CMOS architectures of the type described above offer a number of advantages over competing technologies, these devices also suffer from certain infirmities. For example, existing CMOS devices having a FinFET architecture frequently exhibit reduced threshold voltages, which is an undesirable feature in Non-Volatile Memory (NVM) applications.

There is thus a need in the art for a FINFET CMOS architecture, and for a method for making the same, which overcomes the aforementioned infirmities. In particular, there is a need in the art for a FINFET CMOS architecture which exhibits improved threshold voltage, and which is suitable for use in NVM applications. There is further a need in the art for a method for overcoming the aforementioned infirmities without increasing the complexity or cost of the manufacturing process. These and other needs are met by the devices and methodologies described herein.

### SUMMARY OF THE DISCLOSURE

In one aspect, a semiconductor device is provided herein which comprises (a) a semiconductor substrate; (b) a fin comprising a semiconductor material and being in electrical contact with said substrate; (c) a first floating gate disposed on a first side of said fin; and (e) a control gate.

In another aspect, an NVRAM device is provided which comprises (a) a transistor body having first and second sides and being in electrical contact with a semiconductor substrate; (b) first and second floating gates disposed, respectively, on said first and second sides of said transistor body and being adapted to store a memory signal for the NVRAM device; and (c) a gate dielectric disposed between said transistor body and said first and second floating gates.

In still another aspect, a method for fabricating a semiconductor device is provided. In accordance with the method, a semiconductor substrate is provided, and a fin is formed that is in electrical contact with the substrate. A first dielectric material is deposited on the fin, and a first conductive material is deposited on the first dielectric material. At least one floating gate is defined in the first conductive material.

These and other aspects of the present disclosure are described in greater detail below.

### BRIEF DESCRIPTION OF THE DRAWINGS

FIG. 1 is a partial perspective view of a prior art FINFET device;

FIG. 2 is a partial perspective view of one embodiment of a wafer during another stage in its manufacture according to the methodology disclosed herein;

FIG. 3 is a partial perspective view of one embodiment of a wafer during another stage in its manufacture according to the methodology disclosed herein;

FIG. 4 is a partial perspective view of one embodiment of a wafer during another stage in its manufacture according to the methodology disclosed herein;

FIG. 5 is a partial perspective view of one embodiment of a wafer during another stage in its manufacture according to the methodology disclosed herein;

FIG. 6 is a partial perspective view of one embodiment of a wafer during another stage in its manufacture according to the methodology disclosed herein;

FIG. 7 is a partial perspective view of one embodiment of a wafer during another stage in its manufacture according to the methodology disclosed herein;

FIG. 8 is a partial cross-sectional view of one embodiment of a wafer during another stage in its manufacture according to the methodology disclosed herein;

FIG. 9 is a partial cross-sectional view of one embodiment of a wafer during another stage in its manufacture according to the methodology disclosed herein;

FIG. 10 is a partial cross-sectional view of one embodiment of a wafer during another stage in its manufacture according to the methodology disclosed herein;

FIG. 11 is a partial cross-sectional view of one embodiment of a wafer during another stage in its manufacture according to the methodology disclosed herein;

FIG. 12 is a partial cross-sectional view of one embodiment of a wafer during another stage in its manufacture according to the methodology disclosed herein;

FIG. 12 is a partial isometric view of one embodiment of a wafer during another stage in its manufacture according to the methodology disclosed herein;

FIG. 13 is a partial cross-sectional view of one embodiment of a wafer during another stage in its manufacture according to the methodology disclosed herein;

FIG. 14 is a partial cross-sectional view of one embodiment of a wafer during another stage in its manufacture according to the methodology disclosed herein;

FIG. 15 is a partial cross-sectional view of one embodiment of a wafer during another stage in its manufacture according to the methodology disclosed herein;

FIG. 16 is a partial cross-sectional view of one embodiment of a wafer during another stage in its manufacture according to the methodology disclosed herein;

FIG. 17 is a partial cross-sectional view of one embodiment of a wafer during another stage in its manufacture according to the methodology disclosed herein;

FIG. 18 is a partial cross-sectional view of one embodiment of a wafer during another stage in its manufacture according to the methodology disclosed herein; and

FIG. 19 is a partial cross-sectional view of one embodiment of a wafer during another stage in its manufacture according to the methodology disclosed herein.

### DETAILED DESCRIPTION

It has now been found that the aforementioned problem with low threshold voltages arises from the lack of body contact in conventional FinFET devices. Without wishing to be bound by theory, it is believed that, when no body contact is present in a CMOS FinFET device, the holes generated by hot electrons will accumulate at the channel-to-source junction, thus forward biasing the junction and effectively reducing the transistor threshold voltage (as by counteracting the charge-trapping effect that results from increasing the threshold voltage). This effect can be eliminated through the provision of a body contact, because such a contact allows holes to flow out of the channel region through the contact. Consequently, CMOS FinFET devices which are made with a body contact in accordance with the teachings herein exhibit improved threshold voltage control by biasing the body of the device. Moreover, the methods disclosed herein for forming such a body contact do not increase the complexity of the device or the manufacturing process, nor do they adversely affect device density. As a further benefit, these methodologies are not limited to SOI wafers, but can be used with bulk silicon starting materials and other less expensive wafer types.

The methodologies disclosed herein may be utilized to impart NVRAM (Non-Volatile Random Access Memory) capability to FinFET devices. By creating an NVRAM floating gate structure on the vertical fins of a FinFET structure, semiconductor devices with NVRAM capability can be made which are more compact. Moreover, the FinFET devices may be sufficiently thin to allow full depletion of the device, thereby reducing current leakage and minimizing the energy requirements for the device. The presence of a body contact in these devices is further advantageous in that these devices can be made to function as flash memory devices, because the semiconductor body can be separately biased from the gates.

In one particularly preferred embodiment of the structures disclosed herein, a FinFET structure is provided which is covered by a layer of conductive floating gate material. The layer of conductive floating gate material is covered by a layer of insulator material, which in turn is covered by a layer of conductive control gate material. The floating gate material is electrically insulated from the surrounding circuits. Once charged, the floating gate is capable of maintaining its charge for extremely long periods of time, thus eliminating the need to continually refresh and recharge the device. The structures may incorporate single or double spacer-like floating gates, covered by single or multiple control gates. The FinFET may be very thin to allow the FinFET to fully deplete during the operation of the semiconductor device. Also, multiple NVRAM FinFET structures of the type described herein can be incorporated into a single, larger semiconductor device.

The methodologies disclosed herein may be better understood with reference to the first non-limiting embodiment depicted in FIGS. 2-12, which illustrate a method for manufacturing an NVRAM device in accordance with the teachings herein. Referring to FIG. 2, the process begins with a structure 101 comprising a semiconductor substrate 103 having a first oxide layer 105 thereon. A nitride layer 107 is formed on the first oxide layer 105 through chemical vapor deposition (CVD) or another suitable process. As explained below, the nitride layer 107 serves as a mask during subsequent etching steps and also serves as a polishing stop layer during subsequent chemical mechanical polishing (CMP).

Although substrate 103 is depicted as a monolithic layer of semiconductor material, other substrates and wafers of varying complexity may be advantageously employed as the substrate. Moreover, while substrate 103 is preferably single crystal silicon, it may comprise other appropriate semiconducting materials, including, but not limited to, Si, Ge, GaP, InAs, InP, SiGe, GaAs, or other III/V compounds.

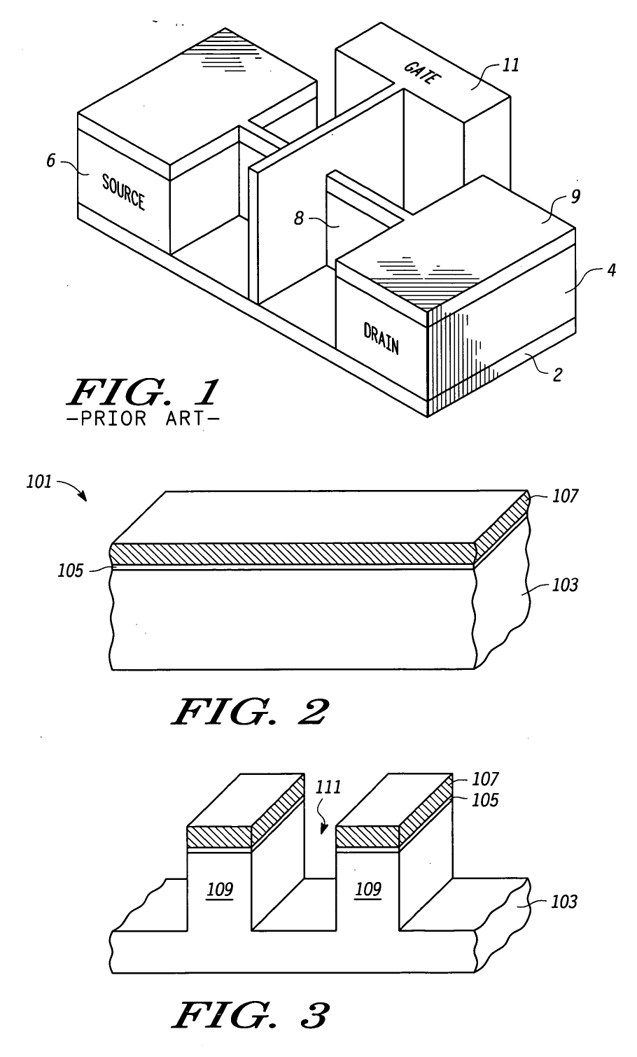

Referring now to FIG. 3, the nitride layer 107 is patterned through a suitable photolithography process. The first oxide layer 105 is patterned, by dry etching or through another suitable technique, using the patterned nitride layer 107 as a mask. An upper portion of the substrate 103 that is adjacent to the first oxide layer 105 is then etched using the nitride layer 107 as a mask to define a plurality of fins 109 therein, with each fin being separated from an adjacent fin by a trench 111. After trench formation, the exposed surfaces of the substrate 103 may be annealed using a suitable material, such as dinitrogen monoxide (N₂O) or nitrogen monoxide (NO), to repair any damage to these surfaces caused by the etching process.

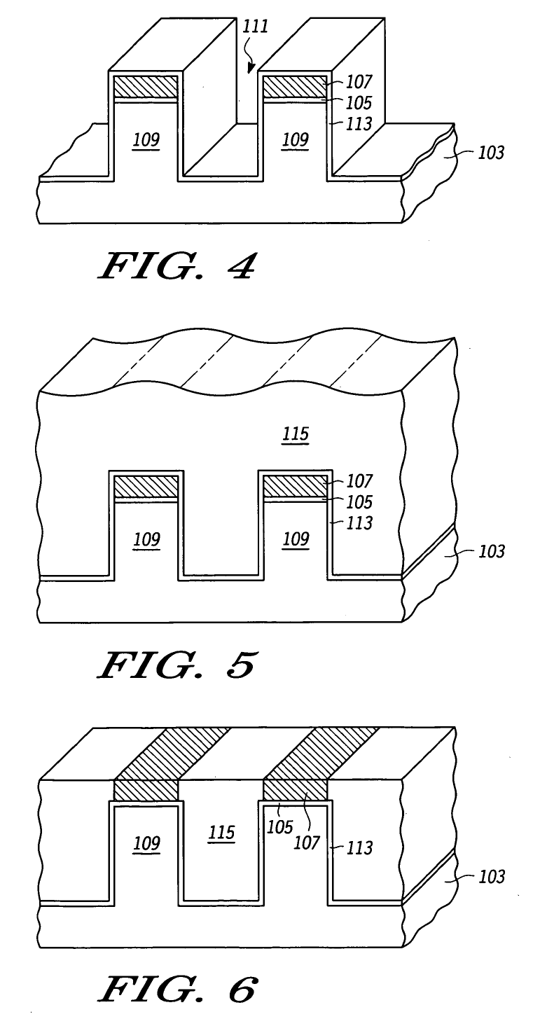

Referring now to FIG. 4, a second oxide layer 113, which preferably comprises a medium temperature oxide, is formed over the structure. The second oxide layer 113 forms a continuous, conformal layer on the exposed surfaces of the substrate 103, including the bottom and sidewalls of the trench 111, and on the exposed surfaces of the nitride layer 107.

Referring to FIG. 5, a third oxide layer 115 is formed over the structure. The third oxide layer 115 may comprise borophosphosilicate glass (BPSG), ozone-tetraethylorthosilicate (O₃-TEOS), undoped silicate glass (USG), or high density plasma (HDP) oxide. The third oxide layer 115 may be formed through a HDP process using silane (SiH₄) gas, oxygen (O₂) gas and argon (Ar) gas as a plasma source.

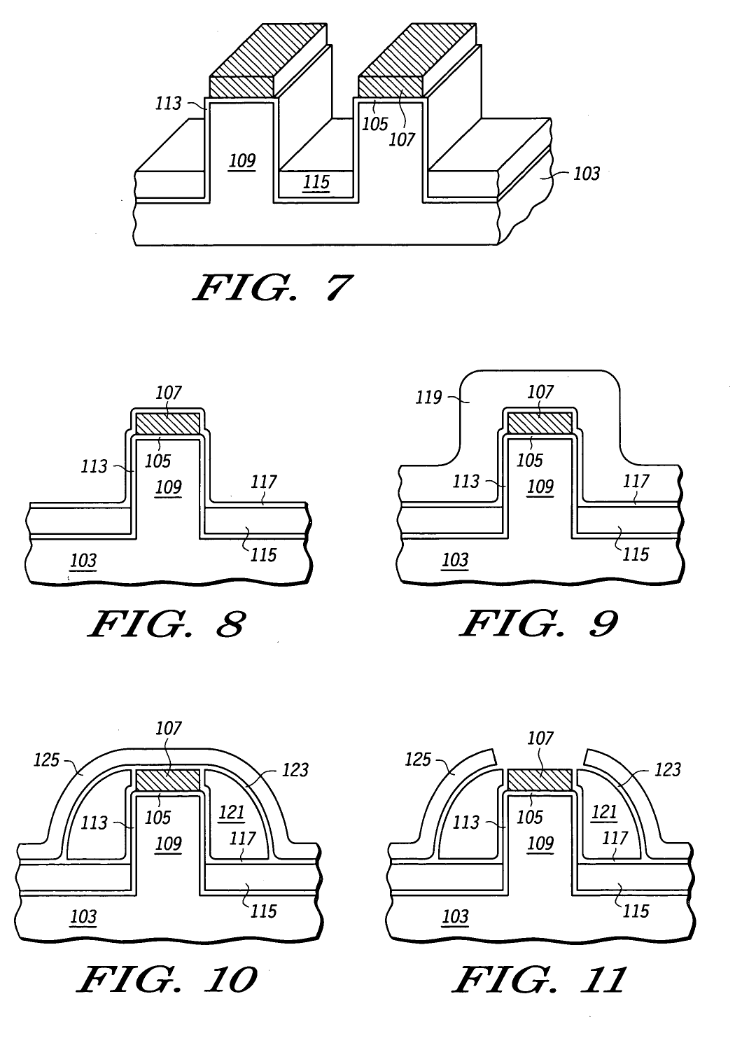

Referring now to FIG. 6, a portion of the third oxide layer 115 is removed through a CMP process to expose the upper surface of the nitride layer 107. The third oxide layer 115 is then etched back as shown in FIG. 7 so that the sides of the fins 109 are exposed. The second oxide layer 113 is depicted in FIG. 7 as being basically unaffected by this etch, though one skilled in the art will appreciate that the exposed portion of this layer may be partially or completely removed in this step, depending on the composition of second oxide layer 113 and the chemistry of the etch.

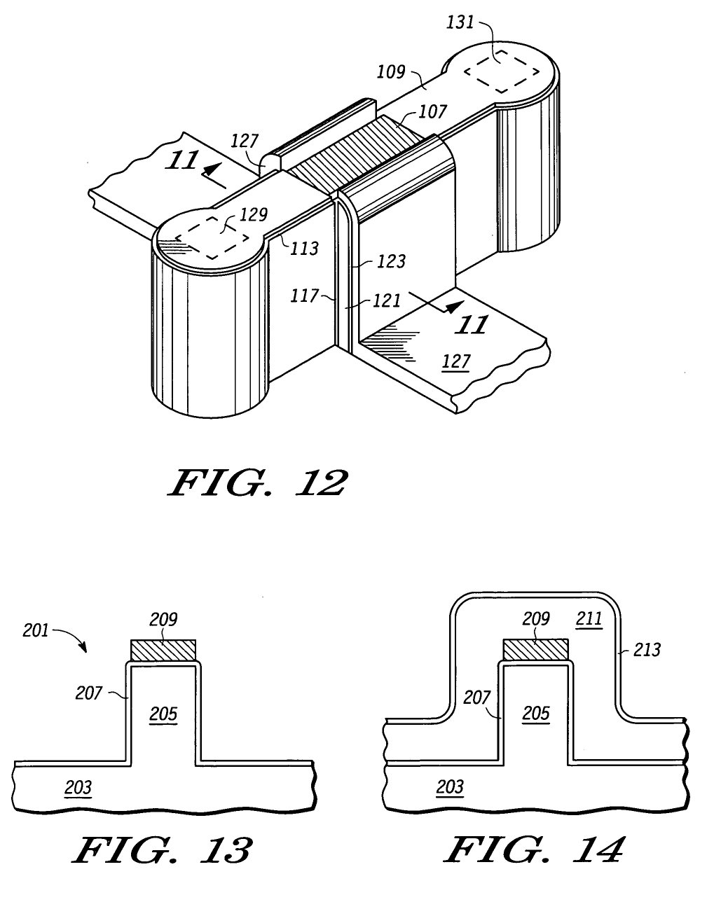

The remainder of the process flow is depicted in FIGS. 8-12. For ease of illustration, FIGS. 8-11 illustrate the processing steps in cross-sectional view and with respect to a single fin in the device, although FIG. 12 shows a perspective view of the device as it appears after these steps.

With respect to FIG. 8, a fourth conformal oxide layer 117 is formed over the structure. This is followed by the deposition of a first layer of polysilicon 119 as shown in FIG. 9. The first layer of polysilicon is then anisotropically etched to form floating gates 121, as shown in FIG. 10, followed by deposition of a fifth oxide layer 123 and a second layer of polysilicon 125. The second layer of polysilicon 125 is used to define the control gates of the device. As indicated in FIG. 11, the second layer of polysilicon 125 may be patterned into multiple independent control gates 127. A perspective view of this structure as it appears at this point in the process is shown in FIG. 12. It will be appreciated that various additional steps may be performed to complete the fabrication of the device, such as implanting source 129 and drain 131 regions in the fins.

In the foregoing method, polysilicon is utilized as the material for both the floating gates 121 and control gates 127. However, while polysilicon is the preferred material for these elements, it will be appreciated that various other gate materials may be substituted for polysilicon. Some non-limiting examples of these materials include tungsten, titanium, tantalum silicon nitride, silicides such as cobalt or nickel silicides, germanium, silicon germanium, other metals, and various combinations of the foregoing.

Several other variations of the foregoing method are also possible. In one such variation, the first oxide layer 105 in FIG. 2 is patterned using the patterned nitride layer 107 as the mask. The substrate 103 is then etched through a self-alignment process using the mask to form the trench 111. Alternatively, the patterned first oxide layer 105 may be formed by suitably patterning the nitride layer 107 and using the patterned nitride layer 107 as a mask. The nitride layer 107 may then be removed. A mask comprising a material that has an etching selectivity relative to silicon may be formed on the substrate 103, and the substrate 103 may be etched to form the trench 111 in the substrate 103 as shown in FIG. 2.

In a further variation, rather then using an etch process to form trenches in the substrate and thereby define one or more semiconductor fins 109, a substrate may be provided which comprises a semiconductor material such as single crystal polysilicon. A photoresist or other suitable masking material may then be deposited on the substrate and patterned to define one or more openings therein, and the substrate may be epitaxially grown to form the fins 109. The fins may be appropriately shaped, if necessary, by subsequent masking and/or etching processes, and one or more oxide or nitride layers may be defined on the tops of the fins through suitable masking and deposition processes.

It should also be noted that, in the foregoing process, a layer of polysilicon or other suitable gate material may be inserted between the first oxide layer 105 and nitride layer 107. This layer of gate material may then be utilized to form a floating gate in later processing steps. If desired, the nitride layer 107 may be removed.

A second (preferred) embodiment of the methodology disclosed herein is depicted in FIGS. 13-17. As seen in FIG. 13, the process of this embodiment starts with a structure 201 similar to that of FIG. 3 which contains a semiconductor substrate 203 which has been patterned to define one or more fins 205 therein. The structure further contains a first oxide layer 207 with a layer of nitride 209 disposed thereon. In the event that a portion of the semiconductor substrate 203 is exposed at this point in the process, thermal oxidation or another suitable technique may be used to create a second (optional) layer of oxide on such exposed surfaces, or to extend the first oxide layer 207. As seen in FIG. 14, a third layer of oxide 211 is then formed over the structure, followed by a layer of nitride 213.

FIG. 15 shows a partial cross sectional view of the structure after deposition of a planar layer 217. Planar layer 217 may comprise various materials, including photo resist, spin-on glass, or organic antireflective coating materials, and may be formed by spin on techniques or by chemical vapor deposition techniques. In some embodiments, formation of layer 217 may be followed by chemical mechanical polish or reflow, although this can be avoided through suitable choice of materials and/or processing techniques.

FIG. 16 shows the structure after planar layer 217 has been etched back by a suitable wet or dry technique to a level below the top portion of nitride layer 213. The degree of etching is selected such that, after the etch back, planar layer 217 is at least thick enough to cover a portion of the vertical segment of nitride layer 213 while exposing the horizontal portion of the nitride layer 213 which extends over the fin 205. In some variations of the present method, rather than depositing the planar layer 217 and etching it back to the desired thickness, a similar result may be achieved by the planar deposition of the material of planar layer 217 to the desired level.

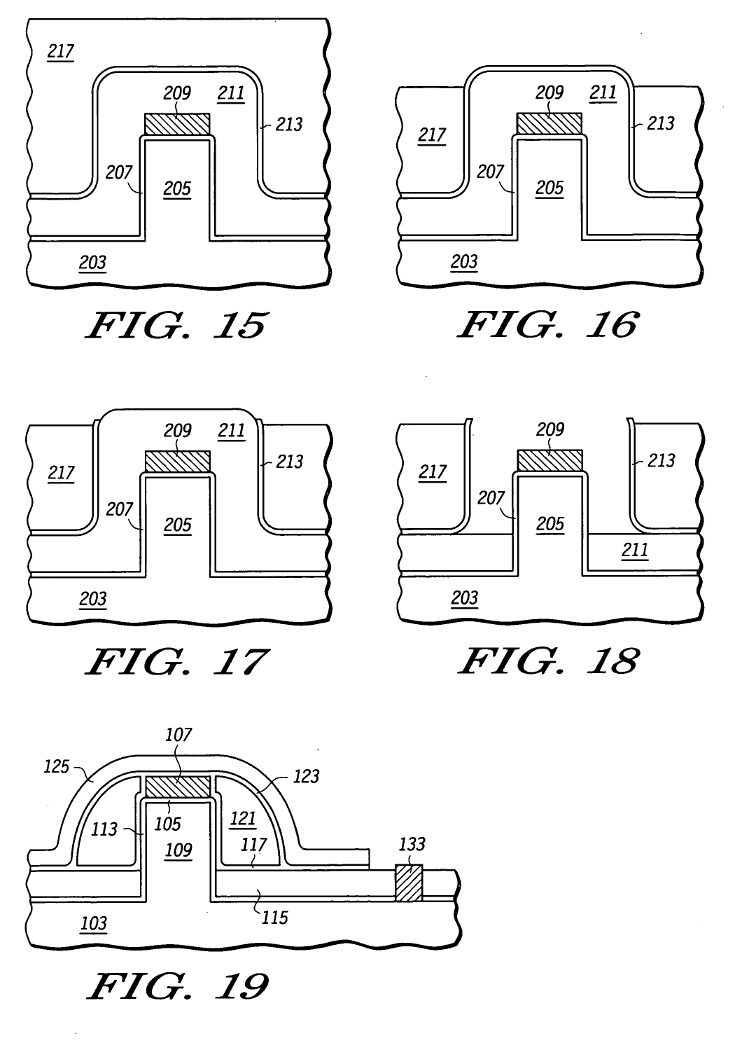

FIG. 17 shows the structure of FIG. 16 after removal of a portion of the nitride layer 213 by etching. Planar layer 217 protects the remaining portion of the nitride layer 213 from being removing during this process. Referring to FIG. 18, after a portion of the nitride layer 213 has been removed, the portion of the third oxide layer 211 previously located under the removed portion of the nitride layer 213 is removed by non-abrasive etching (e.g. wet or dry). Planar layer 217 (along with the remaining portions of nitride layer 213) protects the remaining portions of the third oxide layer 211 from being removed during the etching process. The remaining portions of planar layer 217 and nitride layer 213 may then be removed by suitable wet or dry etching techniques. The device may then be processed using the steps depicted in FIGS. 8-12.

The methodologies described herein result in structures in which the fins 109 and 205 (see FIGS. 11 and 18) containing the channel regions of the device are in electrical contact with the substrate 103 and 203. Accordingly, the channel regions of these devices may be accessed through the substrate 103 and 203 by providing suitable electrical contacts to the substrate (so-called body contacts). The contacts can be appropriately doped at various stages of the processing and can be biased to enable read/write operations of the NVRAM device. FIG. 19 illustrates an example of a device of the type described herein (in this case, the device of FIG. 10) equipped with a body contact 133.

By providing a means to bias the body or fin 109 (see FIG. 12) of the NVRAM device, an operation similar to that of conventional floating gate flash devices can be achieved in these FinFET-based NVRAM devices. For example, in order to program the NVRAM device with electrons, hot-electron injection may be utilized by positively biasing the control gate 127 (or gates) and drain 131 and by grounding the source 129 and the body or fin 109. Uniform channel erase can be performed by negatively biasing the control gate 127 (or gates) with respect to the body or fin 109 and by floating the source 129 and drain 131.

A method for overcoming the problem with low threshold voltages in conventional FinFET devices through the provision of a body contact has been provided herein, along with structures made in accordance with this methodology. CMOS FinFET devices can be made in accordance with the teachings herein which exhibit improved threshold voltage control by biasing the body of the device.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A semiconductor device, comprising:
a semiconductor substrate;
a fin comprising a semiconductor material and being in electrical contact with said substrate;
a first floating gate disposed on a first side of said fin; and
a control gate.

2. The semiconductor device of claim 1, wherein said fin is in physical contact with said substrate.

3. The semiconductor device of claim 1, wherein said first floating gate is electrically insulated from said fin and said control gate.

4. The semiconductor device of claim 1, further comprising a second floating gate disposed on a second side of said fin, and wherein said first floating gate is electrically insulated from said second floating gate.

5. The semiconductor device of claim 1, further comprising a second floating gate disposed on a second side of said fin, and wherein said first floating gate is in electrical contact with said second floating gate.

6. The semiconductor device of claim 1, wherein said substrate has a different conductivity than said fin.

7. The semiconductor device of claim 1, wherein said first floating gate comprises a spacer.

8. The semiconductor device of claim 1, wherein said fin is sufficiently thin to provide full depletion when the device is in operation.

9. The semiconductor device of claim 1, further comprising a semiconductor body region which is in electrical contact with the fin and which is disposed below the fin and the floating gate.

10. The semiconductor device of claim 1, wherein said substrate has a plurality of fins defined thereon, and wherein each of said plurality of fins is in electrical contact with said substrate.

11. An NVRAM device, comprising:
a fin-shaped transistor body having first and second sides and being in electrical contact with a semiconductor substrate;
first and second floating gates disposed, respectively, on said first and second sides of said transistor body and being adapted to store a memory signal; and
a gate dielectric disposed between said transistor body and said first and second floating gates.

12. The NVRAM device of claim 11, further comprising a control gate.

13. The NVRAM device of claim 11, wherein said first and second floating gates are electrically insulated from each other.

14. The NVRAM device of claim 11, wherein said first and second floating gates are in electrical contact with each other.

15. The NVRAM device of claim 11, wherein said fin is sufficiently thick and heavily doped to reduce the influence of the first floating gate on the second floating gate.

16. A method of fabricating a semiconductor device, comprising:
providing a semiconductor substrate;
forming a fin that is in electrical contact with the substrate;
depositing a first dielectric material on the fin;
depositing a first conductive material on the first dielectric material; and
defining at least one floating gate in the first conductive material.

17. The method of claim 16, wherein the step of forming a fin that is in electrical contact with the substrate involves the steps of masking and etching the substrate so as to define the fin therein.

18. The method of claim 16, wherein the step of forming a fin that is in electrical contact with the substrate involves the steps of:
depositing a photoresist on the substrate;
patterning the photoresist so as to expose a portion of the substrate; and
epitaxially growing the exposed portion of the substrate so as to produce a fin which extends from said substrate.

19. The method of claim 16, further comprising the steps of:
depositing a second conductive material; and
defining a control gate in the second conductive material.

20. The method of claim 19, further comprising the step of depositing a second dielectric material, and wherein the second dielectric material is disposed between said fin and said control gate.
